(19) United States
(12) Patent Application Publication
(10) Pub. No.: US 2026/0134919 A1
(43) Pub. Date: May 14, 2026

(54) Method for Implementing Universal Content-Addressable Memory Based on N-Type and P-Type Ferroelectric Field-Effect Transistors

(71) Applicants: BEIJING SUPERSTRING ACADEMY OF MEMORY TECHNOLOGY, Beijing (CN); PEKING UNIVERSITY, Beijing (CN)

(72) Inventors: Qianqian HUANG, Beijing (CN); Weikai XU, Beijing (CN); Ru HUANG, Beijing (CN)

(21) Appl. No.: 19/119,994

(22) PCT Filed: Nov. 9, 2023
(86) PCT No.: PCT/CN2023/130733

§ 371 Date: Apr. 10, 2025

(30) Foreign Application Priority Data
May 26, 2023 (CN) 202310603125.2

(51) Int. Cl. G11C 15/04; G11C 11/22

(52) U.S. Cl. CPC G11C 15/046; G11C 11/223; G11C 11/2275

(57) ABSTRACT

Disclosed is a method for implementing a universal content-addressable memory based on N-type and P-type ferroelectric field-effect transistors, relating to the field of novel storage and computing technology. According to the method, by utilizing the complementary characteristics of N-type FeFET and P-type FeFET, all of TCAM, MACM, and ACAM may be implemented without additional hardware overhead, with a simpler searching operation, the storage density and searching energy efficiency of the CAM being improved, and also with an ability to compress the entry states when quantized as an MCAM storing multi-level entry states, making it possible to further increase the storage density of the CAM, which is of great significance for table lookup search operation based on the CAM.

### CROSS-REFERENCE TO RELATED APPLICATIONS

The present application is a U.S. National Phase Application under 35 U.S.C. 371 of International Application No. PCT/CN 2023/130733, filed on Nov. 9, 2023, which claims priority to Chinese Patent Application No. 202310603125.2, filed with the China National Intellectual Property Administration on May 26, 2023, and entitled “METHOD FOR IMPLEMENTING UNIVERSAL CONTENT-ADDRESSABLE MEMORY BASED ON N-TYPE AND P-TYPE FERROELECTRIC FIELD-EFFECT TRANSISTORS”, disclosures of which are incorporated herein by reference in their entirety.

### FIELD OF THE INVENTION

The present disclosure relates to the field of novel storage and computing technology, and specifically to a design of a universal content-addressable memory based on N-type and P-type ferroelectric field-effect transistors.

### BACKGROUND OF THE INVENTION

A content-addressable memory (CAM) may perform parallel search operations efficiently, and are widely used in routers, database searches, in-memory computing, and efficient machine learning models such as neuromorphic computing. CAM is a special type of memory used for parallel searches, which may perform special search operations in addition to the read and write operations of a conventional memory. CAM is originally used to accelerate table lookup operations related to packet forwarding and classification and so on in network routers. Since the CAM may perform an entire search operation in a single clock cycle, it has a significant acceleration effect compared to other hardware-based or software-based search systems. Based on CAM, a ternary content-addressable memory (CAM) with an ability of storing mask “X” state was further developed, and TCAM may realize precise matching or fuzzy matching to improve the efficiency of table lookup search. In the era of big data, since CAM may complete matching operations between input vectors (query) and all stored vectors (entry) in single search cycle, and perform feature retrieval based on a distance metric according to a degree of mismatch, it is very attractive in dealing with edge-end machine learning tasks such as pattern matching, video and image processing.

A design of a CAM based on conventional static random access memories (SRAMs) occupies a large cell area, limiting their storage density for compute-intensive algorithm mapping, and the resulting large parasitic capacitance further increases search latency and power consumption. CAMs designed based on various emerging nonvolatile memories, such as resistive random access memory (RRAM), phase change memory (PCM), and ferroelectric field-effect transistors (FeFETs) have reduced cell area and reduced search latency and power consumption. In addition, multi-bit content-addressable memories (MCAMs) and analog content-addressable memories (ACAMs), which are designed further by utilizing the multi-bit storage capability of emerging nonvolatile memories, may not only improve the storage density of CAMs, but also may be used for a wider range of application scenarios such as decision trees and deep random forests based on the special range-matching operation of ACAM.

However, various CAM designs based on emerging non-volatile memories require different hardware overheads, and MCAM and ACAM designs need to be implemented by additional hardware overheads, i.e., additional control transistors or additional peripheral complex circuits being used for matching operations of analog or multi-bit inputs and storage ranges, and correspondingly programming and searching methods are also more complex. Therefore, implementing of compact and simple TCAM, MCAM, and ACAM designs without additional hardware cost is of great significance for further increasing the density and expanding the functionality of CAMs.

### SUMMARY OF THE INVENTION

For the above problems in the prior art, the present application proposes a design of a universal CAM based on N-type and P-type FeFETs, which may realize the functions of all of TCAM, MACM, and ACAM without additional hardware overhead by utilizing complementary characteristics of N-type FeFET and P-type FeFET, with a simpler searching operation, the storage density and searching energy efficiency of the CAM being improved, and the application scenarios of CAM being expanded.

The technical program of the invention is as follows:

A method for implementing a universal CAM based on complementary FeFETs, characterized in that
1) the content-addressable memory CAM cell with two FeFETs connected in parallel is formed, one of which is an N-type FeFET and the other one of which is a P-type FeFET, the two FeFETs having drains connected as a match line (ML) of the CAM cell for detecting whether a search query matches a stored entry during a search operation, sources commonly connected to the ground, and gates, which are connected to two bit lines during programming, respectively, and to a same search line (SL), during searching, for applying a search voltage corresponding to the search query;
2) a certain programming voltage is applied to the gates of N-type FeFET and P-type FeFET, respectively, at a phrase of storing entries during the programming CAM cell, to program them to different threshold voltage states, which are reflected, in device transfer characteristic curves, as that a gate voltage when a drain current is smallest as translating along the gate voltage is called as V_{OFF}, wherein, for entry 0, the two FeFETs are programmed to V_{OFF0} state; and for entry 1, the two FeFETs are programmed to V_{OFF1} state;
3) A voltage V_{SL0} equal to V_{OFF0} is applied to SL for query 0, and a voltage V_{SL1} equal to V_{OFF1} is applied to SL for query 1, in a search phase. Accordingly, only when the query matches the entry, the two FeFETs of each of the CAM cells are both in a cutoff state, having a lower draining current, indicating matching; otherwise, one of the two FeFETs is in a turn-on state, having a higher draining current, indicating mismatching. For entry X, the P-type FeFET is programmed to the V_{OFF0} state and the N-type FeFET is programmed to the V_{OFF1} state; and for any of the search queries, the two FeFETs are both in a cutoff state, indicating matching.

Further, the two FeFETs of the CAM cell are programmed to have the same plurality of V_{OFF} states, i.e., quantized as an MCAM cell, wherein the plurality of V_{OFF} states represent discrete multiple-level stored entries, and the quantized search query has V_{SL} equal to a corresponding V_{OFF}. When searching, a corresponding search voltage V_{SL} is applied to SL according to the search query, and only when the search query is in conformity with the stored entry, V_{SL} is equal to V_{OFF} and the two FeFETs are both in the cutoff state. Further, the N-type FeFET and the P-type FeFET of the MCAM cell are programmed to different V_{OFF} states, and the search queries corresponding to the V_{SL} between the two V_{OFF} states are both matched, implementing a function of entry compression.

Further, a function of an ACAM cell may be implemented by programming the threshold voltages of the N-type FeFET and the P-type FeFET of the CAM cell to be V_{THN} and V_{(THP)}, respectively, wherein V_{(THN})>V_{THP}. The ACAM cell stores entries with a matching range of [V_{THP}, V_{THN}], and its corresponding drain current is I_{Ref}. In the search phrase, a certain voltage V_{SL} is applied to SL, having a magnitude corresponding to the search query; wherein only when V_{SL} is within the matching range, a ML current of the ACAM cell is less than I_{Ref}, indicating that the search query match the range of the stored entries. When V_{ST} is less than a lower boundary V_{THP} of the matching range, a current of the P-type FeFET is made to be greater than I_{Ref}, and when V_{SL} is greater than an upper boundary V_{THN} of the matching range, a current of the N-type FeFET is made to be greater than I_{Ref}, that is, the ML current is greater than I_{Ref}, indicating that the search query mismatches the range of the stored entry, realizing the search operation of the ACAM cell.

Further, an array is formed with a plurality of CAM cells, each row of the CAM cells sharing ML, wherein according to input vectors of queries, corresponding analog search voltages are applied to all SL terminals at the same time; and depending on different mismatches between vectors of the search queries and vectors of the stored entries, each of the CAM cells can have a current positively correlated to a mismatch degree with the bit, ML for each row in the array accumulates the current of each CAM cell, and the magnitude of this current being positively correlated with a mismatch degree between vectors of the search query and stored entry, and an application such as distance metrology being realized according to the magnitude of the current.

In summary, the complementary and symmetric transfer characteristics of N-type FeFET and P-type FeFET may be utilized to realize TCAM, MCAM with entry compression, and ACAM functions without additional hardware overhead, and applications such as distance metrology may be further realized based on the CAM array.

The present disclosure proposes a generalized CAM design based on N-type and P-type FeFETs, in which the ferroelectric materials need to be of various types of HfO₂-doped multi-domain ferroelectric materials such as HfO₂-doped Zr (HZO), HfO₂-doped Al (HfAlO), etc., and device gate stacks may be based on a wide range of structures, such as MFMIS, MFIS, MFS, and so on.

The present application have technical effects as follows:
1. For the generalized CAM design based on N-type and P-type FeFETs proposed in the present disclosure, the complementary and symmetric transfer characteristics of the N-type FeFET and P-type FeFET are utilized to implement TCAM cells, and to implement MCAM cells and ACAM cells without additional hardware overhead, the storage density and the searching energy efficiency of the CAMs being improved, and the application scenarios of the CAMs being expanded.
2. The generalized CAM design based on N-type and P-type FeFETs proposed in the present disclosure also has an ability to compress the entry states when quantized as an MCAM storing multiple-level entry states, making it possible to further increase the storage density of the CAM, which is of great significance for table lookup search operation based on the CAM.

### BRIEF DESCRIPTION OF THE DRAWINGS

FIG. 1 shows a schematic diagram of a cell structure of a design of a universal CAM based on N-type and P-type FeFETs according to the present application;

FIG. 2 shows a functional schematic diagram of the universal CAM based on N-type and P-type FeFETs according to the present application when used for TCAM;

FIG. 3 shows the functional schematic diagram of the universal CAM based on N-type and P-type FeFETs according to the present application when used for MCAM;

FIG. 4 shows the functional schematic diagram of the universal CAM based on N-type and P-type FeFETs according to the present application when used for ACAM.

### DETAILED DESCRIPTION OF THE EMBODIMENTS

The present disclosure is hereinafter further described clearly and completely with reference to embodiments in conjunction with the accompanying drawings.

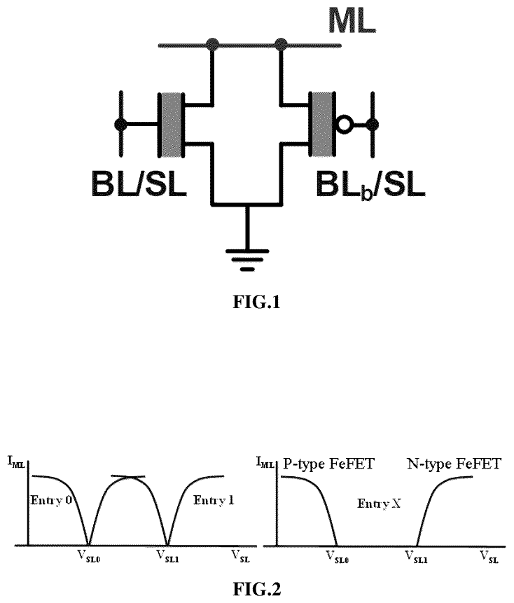

The cell structure of the design of the universal CAM based on N-type and P-type FeFETs according to the present disclosure is schematically shown in FIG. 1, wherein a CAM cell includes one N-type FeFET and one P-type FeFET connected in parallel. The two FeFETs connected in parallel have drains connected to a ML, for detecting whether a query matches an entry in a searching operation; sources connected to the ground; and gates, which are connected to two bit lines, respectively, for applying a programming voltage during a programming operation, and which are connected to a same SL during the search operation, for applying a search voltage corresponding to the query. FIG. 2 shows a functional schematic diagram of the universal CAM based on N-type and P-type FeFETs according to the present embodiment when used for TCAM. In a programming phrase, a certain programming voltage is applied to the N-type FeFET and the P-type FeFET, respectively, where the two FeFETs are programmed to a V_{OFF0} state for entry 0, and are programmed to a V_{OFF1} state for entry 0, and the P-type FeFET is programmed to the V_{OFF0} state and the N-type FeFET is programmed to the V_{OFF1} state for entry X. In a search phase, a voltage V_{SL0}=V_{OFF0} is applied to SL for query 0, and a voltage V_{SL1}=V_{OFF1} is applied to SL for query 1. Thus, only when the search query is in conformity with the stored entry, both of the FeFETs are cutoff, indicating a match.

FIG. 3 shows a functional schematic diagram of the universal CAM based on N-type and P-type FeFETs according to the present embodiment when used for MCAM. a 2-bit MCAM is taken as an example, by programming the CAM cell to four non-overlapping matching ranges representing entries “00”, “01”, “10”, and “11” for the 2-bit MCAM cell, respectively, a search query is a center voltage value of a storage range of a corresponding entry. During the search, a corresponding search voltage is applied according to a query, and only when the search query is in conformity with the stored entries, V_{SL} is located within the matching range, indicating a match; otherwise, V_{SL} may be located outside the matching range, and a greater current may be detected at the ML end, indicating a mismatch. Further the entries “00” and “01” of the MCAM cell may be programmed into a single matching range, then the storage state may be denoted as entry “0X”, that is, for either of the search queries “00” and “01”, entry “0X” may match. Similarly, the entries “10” and “01” of the MCAM cell may be programmed into a single matching range, then the storage state may be denoted as entry “1X”, and for either of the search query “10” and “01”, entry “1X” may match. Furthermore, “0X” and “10” may be programmed into a single matching range, and may be programmed as “XX” state similar to an entry X in TCAM, indicating match for all of the search queries.

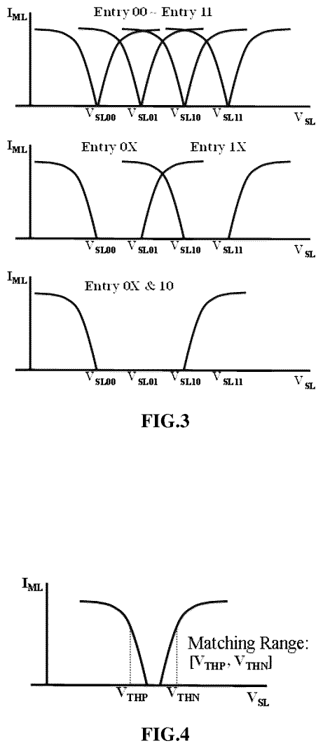

FIG. 4 shows a functional schematic diagram of the universal CAM based on N-type and P-type FeFETs according to the present embodiment when used for an ACAM. In the programming phrase, a certain programming voltage is applied to the N-type FeFET and P-type FeFET, respectively, and a threshold voltage of the N-type FeFET is programmed to V_{THN}, and a threshold voltage of the P-type FeFET is programmed to V_{THP}, where it is necessary to ensure V_{THP}<V_{THN}, indicating that this ACAM cell is programmed to a state with a matching range [V_{THP}, V_{THN}], and its corresponding drain current is I_{Ref}. In the search phase, a certain voltage V_{SL} is applied to SL, having a magnitude corresponding to the search query. Only when V_{SL} is within the matching range, a ML current of the ACAM cell may be made to be less than I_{Ref}, indicating that the search query matches a range of the stored entries. When V_{SL} is less than a lower boundary V_{THP} of the matching range, the current of the P-type FeFET may be made to be greater than I_{Ref}, and when V_{SL} is greater than an upper boundary V_{THN} of the matching range, the current of the N-type FeFET may be made to be greater than I_{Ref}, that is, the current of the ML is greater than I_{Ref}, indicating that the search query mismatches the range of the stored entries.

The present embodiment provides a complete and detailed description that the universal CAM cell based on N-type and P-type FeFETs realizes functions of TCAM, MCAM, and ACAM without additional hardware overhead, expanding the application scenarios of CAM.

Finally, it should be noted that the disclosure of the embodiments is intended to aid in the further understanding of the present disclosure, but it may be understood by those skilled in the art that various substitutions and modifications are possible without departing from the spirit and scope of the present disclosure and the appended claims. Therefore, the present disclosure should not be limited to what are disclosed in the embodiments, and the scope of protection claimed by the present disclosure is based on the scope defined in the claims.

What is claimed is:

1. A method for implementing a universal content-addressable memory based on N-type and P-type ferroelectric field-effect transistors, comprising:
1) forming the content-addressable memory CAM cell with two FeFETs connected in parallel, one of which is an N-type FeFET and the other one of which is a P-type FeFET, the two FeFETs having drains connected as a match line of the CAM cell for detecting whether a search query matches a stored entry during a search operation, sources commonly connected to the ground, and gates, which are connected to two bit lines during programming, respectively, and to a same search line, during searching, for applying a search voltage corresponding to the search query;
2) applying a certain programming voltage to the gates of N-type FeFET and P-type FeFET, respectively, at a phrase of storing entries during the programming CAM cell, to program them to different threshold voltage states, which are reflected, in device transfer characteristic curves, as that a gate voltage when a drain current is smallest as translating along the gate voltage is called as V_{OFF}, wherein, for entry 0, the two FeFETs are programmed to V_{OFF0} state; for entry 1, the two FeFETs are programmed to V_{OFF1} state; and for entry X, the P-type FeFET is programmed to the V_{OFF0} state and the N-type FeFET is programmed to the V_{OFF1} state;
3) applying a voltage V_{SL0} equal to V_{OFF0} to SL for query 0, and applying a voltage V_{SL1} equal to V_{OFF1} to SL for query 1, in a search phase, wherein when the query matches the entry, the two FeFETs of the CAM cell are both in a cutoff state, indicating matching; otherwise, one of the two FeFETs is in a turn-on state, indicating mismatching.

2. The method as claimed in claim 1, characterized by programming the two FeFETs of the CAM cell to have the same plurality of V_{OFF} states, i.e., realizing quantization as an MCAM cell, wherein the plurality of V_{OFF} states represent discrete multiple-level stored entries, and the quantized search query has V_{SL} equal to a corresponding V_{OFF}; and when searching, a corresponding search voltage V_{SL} is applied to SL according to the search query, and only when the search query is in conformity with the stored entry, V_{SL} is equal to V_{OFF} and the two FeFETs are both in the cutoff state.

3. The method as claimed in claim 2, characterized by programming the N-type FeFET and the P-type FeFET of the MCAM cell to different V_{OFF} states, wherein the search queries corresponding to the V_{SL} between the two V_{OFF} states are both matched, implementing a function of entry compression.

4. The method as claimed in claim 1, characterized by programming the threshold voltages of the N-type FeFET and P-type FeFET of the CAM cell to be V_{THN} and V_{THP}, respectively, wherein V_{THN}>V_{THP}, a function of an ACAM cell being implemented, wherein the ACAM cell stores entries with a matching range of [V_{THP}, V_{THN}], and its corresponding drain current is I_{Ref}, wherein in the search phrase, a certain voltage V_{SL} is applied to SL, having a magnitude corresponding to the search query; wherein when V_{SL} is within the matching range, a ML current of the ACAM cell is less than I_{Ref}, indicating that the search query match the range of the stored entries; and when V_{SL} is less than a lower boundary V_{THP} of the matching range, a current of the P-type FeFET is greater than I_{Ref}, and when V_{SL} is greater than an upper boundary V_{THN} of the matching range, a current of the N-type FeFET is greater than I_{Ref}, that is, the ML current is greater than I_{Ref}, indicating that the search query mismatches the range of the stored entry.

5. The method as claimed in claim 1, characterized by forming an array with a plurality of CAM cells, each row of the CAM cells sharing ML, wherein according to input vectors of queries, corresponding analog search voltages are applied to all SL terminals at the same time; and
depending on different mismatches between vectors of the search queries and vectors of the stored entries, each of the CAM cells can have a current positively correlated to a mismatch degree with the bit, ML for each row in the array accumulates the current of each CAM cell, and the magnitude of this current being positively correlated with a mismatch degree between vectors of the search query and stored entry, and an application of distance metrology being realized according to the magnitude of the current.
